(19) United States
(12) Patent Application Publication
(10) Pub. No.: US 2020/0194454 A1
(43) Pub. Date: Jun. 18, 2020

(54) VERTICAL MEMORY DEVICE

(71) Applicant: Samsung Electronics Co., Ltd., Suwon-si (KR)

(72) Inventor: Gang ZHANG, Suwon-si (KR)

(21) Appl. No.: 16/515,113

(22) Filed: Jul. 18, 2019

(30) Foreign Application Priority Data
Dec. 14, 2018 (KR) 10-2018-0161836

(51) Int. Cl. H01L 27/11582; H01L 27/11524; H01L 27/11556; H01L 27/11529; H01L 27/1157; H01L 27/11573; H01L 23/00

(52) U.S. Cl. CPC H01L 27/11582; H01L 27/11524; H01L 27/11556; H01L 23/562; H01L 27/1157; H01L 27/11573; H01L 27/11529

(57) ABSTRACT

A vertical memory device includes a semiconductor layer disposed on a substrate, a first gate electrode layer and a second gate electrode layer stacked on the semiconductor layer, separation patterns penetrating the first gate electrode layer and the second gate electrode layer in a direction perpendicular to an upper surface of the substrate, and extending in a direction parallel to the upper surface of the substrate, and supporting insulating layers penetrating the semiconductor layer and the substrate, and disposed below the separation patterns to respectively vertically overlap the separation patterns.

### CROSS-REFERENCE TO RELATED APPLICATION(S)

This application claims priority to Korean Patent Application No. 10-2018-0161836 filed on Dec. 14, 2018 in the Korean Intellectual Property Office, the disclosure of which is herein incorporated by reference in its entirety.

### BACKGROUND

### 1. Field

The present inventive concept relates to a vertical memory device.

### 2. Description of Related Art

The sizes of electronic products have gradually been reduced, while such electronic products are still required to process high capacity data. Thus, the degree of integration of semiconductor memory devices used in such electronic products has been increased. In products in which the degree of integration of semiconductor memory devices may be increased, vertical memory devices, in which memory cells are stacked to have a vertical transistor structure, rather than a planar transistor structure, are being manufactured. However, manufacturing these vertical memory devices can include a number of complex processes.

### SUMMARY

An example embodiment of the present inventive concept is to provide a vertical memory device in which a manufacturing process such as a process of etching channel holes, or the like, is simplified and operational reliability is improved.

According to some example embodiments of the present inventive concept, a vertical memory device may include: a semiconductor layer disposed on a substrate; a first gate electrode layer and a second gate electrode layer stacked on the semiconductor layer; separation patterns penetrating the first gate electrode layer and the second gate electrode layer in a direction perpendicular to an upper surface of the substrate, and extending in a direction parallel to the upper surface of the substrate; and supporting insulating layers penetrating the semiconductor layer and the substrate, and disposed below the separation patterns to respectively vertically overlap the separation patterns.

According to some example embodiments of the present inventive concept, which in some cases are the same as the above example, a vertical memory device may include: a semiconductor layer disposed on a substrate; supporting insulating layers penetrating the semiconductor layer and the substrate; separation patterns disposed on the semiconductor layer, and overlapping the supporting insulating layers in a direction perpendicular to the upper surface of the substrate; a stack structure disposed between the separation patterns, and including a plurality of gate electrode layers stacked on the substrate; and vertical structures penetrating the stack structure, each vertical structure including a channel that contacts the semiconductor layer.

According to some example embodiments of the present inventive concept, which may be the same embodiment as the above examples, a vertical memory device may include: a base substrate; transistors disposed on the base substrate and constituting a peripheral circuit; an interlayer insulating layer covering the transistors; a substrate disposed on the interlayer insulating layer, and having a smaller size than that of the base substrate; a semiconductor layer disposed on the substrate; supporting insulating layers penetrating the semiconductor layer and the substrate; a stack structure including a plurality of gate electrode layers stacked on the semiconductor layer; separation patterns penetrating the stack structure and overlapping the supporting insulating layers in a direction perpendicular to an upper surface of the substrate; and vertical structures penetrating the stack structure, each including a channel that contacts the semiconductor layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a layout diagram schematically illustrating a vertical memory device according to an example embodiment;

FIGS. 2 and 3 are cross-sectional views illustrating a vertical memory device according to an example embodiment;

FIGS. 4A and 4B are cross-sectional views illustrating a portion of a vertical memory device according to example embodiments, corresponding to region ‘A’ of FIG. 2;

FIG. 5 is a cross-sectional view illustrating a vertical memory device according to an example embodiment; and

FIGS. 6 to 17 are cross-sectional views schematically illustrating a manufacturing method of a vertical memory device according to an example embodiment.

### DETAILED DESCRIPTION

Hereinafter, example embodiments of the present inventive concept will be described with reference to the accompanying drawings.

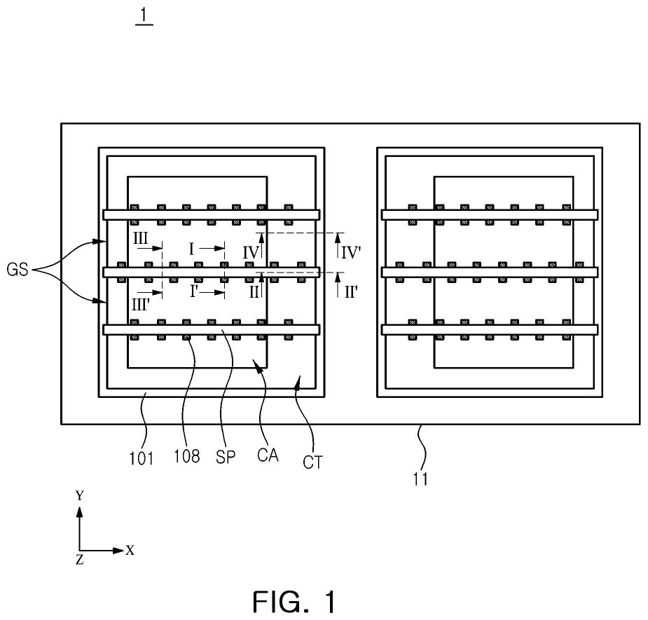

FIG. 1 is a layout diagram schematically illustrating a vertical memory device according to an example embodiment. The vertical memory device may be a semiconductor package, for example, including a package substrate and semiconductor chips formed thereon, and encapsulated by an encapsulation layer. The semiconductor chips may each be formed on a die manufactured from a semiconductor wafer.

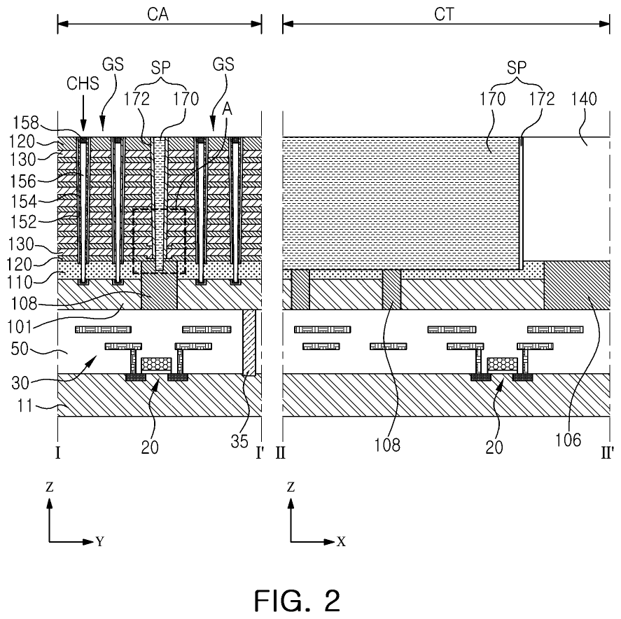

Referring to FIG. 1, a vertical memory device 1 may include substrates 101 disposed on a base substrate 11, separation patterns SP extending in a first direction (x direction) in a cell array region CA and a connection region CT of the substrates 101, and supporting insulating layers 108 disposed below the separation patterns SP. The base substrate 11 may be a package substrate or may be mounted on a package substrate to complete a semiconductor package. Sizes of the substrates 101 may be smaller than a size of the base substrate 11. Also, thought two substrates 101 are shown, greater or fewer than two substrates may be included as part of the vertical memory device, for example, as part of a semiconductor package. The separation patterns SP may be disposed at specific intervals in a second direction (y direction) intersecting the first direction (x direction). The cell array region CA may be provided with stack structures GS, separated from each other by the separation patterns SP. The connection region CT may be disposed to surround the cell array region CA, and the stack structures GS may extend in the first direction (x direction) and may also be disposed in the connection region CT. Components described as extending in a particular direction have a length in that direction and width in a direction perpendicular to that direction, wherein the length is greater than the width. The cell array region CA may be provided with vertical structures (CHS, referring to FIG. 2), penetrating the stack structures GS in a third direction (z direction) intersecting the first direction (x direction) and the second direction (y direction). The first direction (x direction) and the second direction (y direction) may be parallel to the upper surface of the substrate 101, and the third direction (z direction) may be perpendicular to the upper surface of the substrate 101.

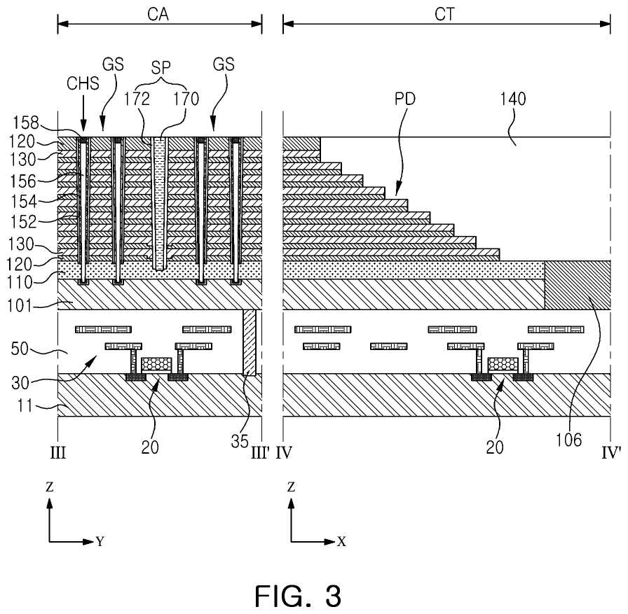

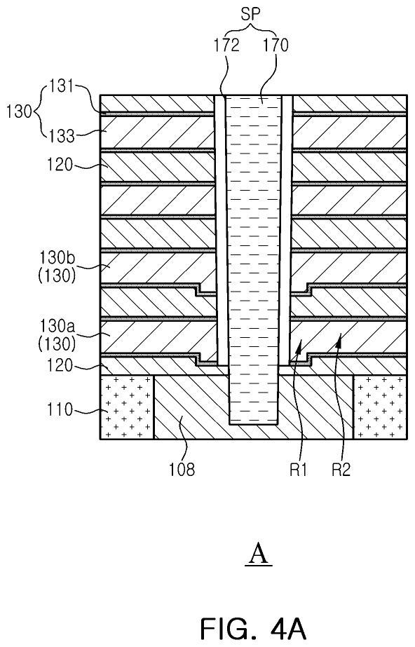

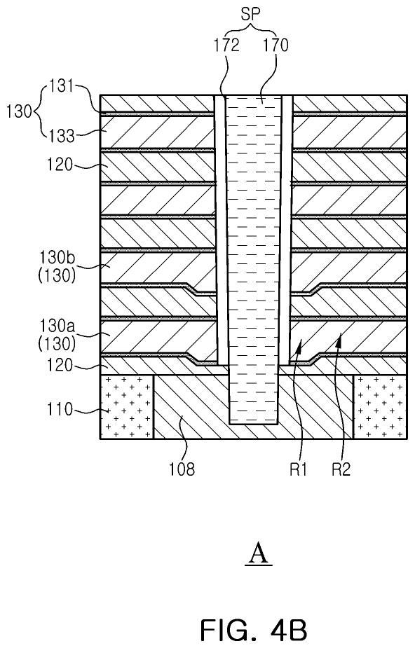

FIGS. 2 and 3 are cross-sectional views illustrating a vertical memory device according to an example embodiment. FIGS. 4A and 4B are cross-sectional views illustrating a portion of a vertical memory device according to example embodiments, and are cross-sectional views corresponding to region ‘A’ of FIG. 2.

Referring to FIGS. 2 and 3, a vertical memory device 1 may include transistors 20 formed on a base substrate 11, circuit wirings 30, an interlayer insulating layer 50, and a contact plug 35. Though only a certain number of these components is shown in the figures, it should be understood that an actual vertical memory device 1 will include a larger number of most or all of these components, and different vertical memory devices can include different numbers of these components. The base substrate 11 may include and may be a semiconductor material such as a Group IV semiconductor, a Group III-V compound semiconductor or a Group II-VI compound semiconductor. The Group IV semiconductor may be, for example, silicon, germanium or silicon-germanium. For example, the base substrate 11 may be single-crystal silicon. The transistors 20 and the circuit wirings 30 may constitute a peripheral circuit. The transistors 20 may include planar transistors, as well as various types of transistors. The contact plug 35 may penetrate the interlayer insulating layer 50. The contact plug 35 may be formed of, for example, polycrystalline silicon and may be a conductive plug having, for example, a vertical pillar shape.

The vertical memory device 1 may include a substrate 101 disposed on an interlayer insulating layer 50, a semiconductor layer 110 disposed on the substrate 101, supporting insulating layers 108 penetrating the semiconductor layer 110 and the substrate 101, an interlayer insulating layer 106 disposed on the interlayer insulating layer 50 and surrounding a periphery of the substrate 101, a stack structure GS disposed on the semiconductor layer 110, a vertical channel structure CHS penetrating the stack structure GS and the semiconductor layer 110, and a separation pattern SP disposed on the supporting insulating layers 108 and separating the stack structures GS from each other.

The substrate 101 and the semiconductor layer 110 may each be formed of a semiconductor material, such as a Group IV semiconductor, a Group III-V compound semiconductor, or a Group II-VI compound semiconductor. For example, the substrate 101 may be formed of undoped polycrystalline silicon, or polycrystalline silicon including n-type impurities. The semiconductor layer 110 may be formed of polycrystalline silicon including n-type impurities. The semiconductor layer 110 may contact the upper surface of the substrate 101, and may cover the upper surface of the substrate 101. Items described herein as contacting each other are directly connected to each other (e.g., touch each other). Upper surfaces of the supporting insulating layers 108 and an upper surface of the interlayer insulating layer 106 may be at the same vertical level as (and thus coplanar with) an upper surface of the semiconductor layer 110 immediately adjacent to the supporting insulating layers 108 or interlayer insulating layer 106. Lower surfaces of the supporting insulating layers 108 and a lower surface of the interlayer insulating layer 106 may be at the same vertical level as (and thus coplanar with) a lower surface of the substrate 101. In an example embodiment, the lower surfaces of the supporting insulating layers 108 and the lower surface of the interlayer insulating layer 106 may be lower than the lower surface of the substrate 101. In these embodiments, each of the supporting insulating layers 108 and the interlayer insulating layer 106 may extend continuously from a lower surface of the substrate 101 to an upper surface of the semiconductor layer 110. The supporting insulating layers 108 and the interlayer insulating layer 106 may be formed of, for example, an insulating material such as silicon oxide. The substrate 101 may be electrically connected to the base substrate 11 by the contact plug 35.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The stack structure GS may include mold insulating layers 120 and gate electrode layers 130, which are alternately stacked on the semiconductor layer 110. The stack structure GS may form a stepped structure in the connection region CT to provide pads PD. Gate contact plugs (not illustrated) penetrating an interlayer insulating layer 140, covering the stepped structure to be connected to the pads PD, may be formed. The mold insulating layers 120 may be formed of, for example, silicon oxide. The gate electrode layers 130 may include and be formed of at least one of a metal, a metal nitride, a metal silicide, and polycrystalline silicon. The semiconductor layer 110 may contact a lower surface of the mold insulating layer 120, located at a lowermost portion of the stack structure GS.

A vertical channel structure CHS may include a gate insulating layer 152, a channel 154, a gap fill insulating layer 156, and a pad 158. The vertical channel structure CHS may penetrate the stack structure GS and the semiconductor layer 110 in a third direction (z direction) perpendicular to the upper surface of the substrate 101. A lower end of the vertical channel structure CHS may be inserted into an upper portion of the substrate 101. The gate insulating layer 152 may surround the channel 154, and the channel 154 may surround the gap fill insulating layer 156. A lower end of the gap fill insulating layer 156 may be lower than the upper surface of the substrate 101. A portion of the channel 154 and a portion of the gate insulating layer 152 may be disposed within the upper portion of the substrate 101 while surrounding the lower end of the gap fill insulating layer 156. The semiconductor layer 110 may penetrate the gate insulating layer 152 and the channel 154 to contact the gap fill insulating layer 156. The channel 154 may contact the upper portion and the lower portion of the semiconductor layer 110.

The gate insulating layer 152 may include a tunneling layer, a charge storage layer, and a blocking layer. The tunneling layer may be, for example, silicon oxide. The charge storage layer may be, for example, silicon nitride. The blocking layer may be silicon oxide (SiO₂), silicon nitride (Si₃N₄), silicon oxynitride (SiON), a high-dielectric constant (high-k) material, or a combination thereof. The high-dielectric constant (high-k) material may be metal oxide having a dielectric constant higher than that of silicon oxide. The high-dielectric constant (high-k) material may be any one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The channel 154 may be, for example, undoped polycrystalline silicon. The gap fill insulating layer 156 may be, for example, silicon oxide. The pad 158 may be a conductive material such as polycrystalline silicon including n-type impurities.

The separation pattern SP penetrates the stack structure GS in the third direction (z direction), extends in a first direction (x direction), and may include a conductive layer 170 and an insulating layer 172 in spacer form. The supporting insulating layers 108 may be disposed below the separation pattern SP, and the conductive layer 170 may contact the supporting insulating layers 108 and the semiconductor layer 110. A lower surface of the conductive layer 170 may be lower than the upper surface of the semiconductor layer 110. A lower portion of the conductive layer 170 may be inserted into upper portions of the supporting insulating layers 108. The conductive layer 170 may be a common source line, for example.

Referring to FIGS. 4A and 4B, two gate electrode layers 130a and 130b, adjacent to the supporting insulating layers 108 among the gate electrode layers 130 may include a first region R1, adjacent to the separation pattern SP and a second region R2, adjacent to the first region R1, and the first region R1 may be disposed between the separation pattern SP and the second region R2, and a thickness of the first region R1 in the third direction (z direction) may be greater than a thickness of the second region R2 in the third direction (z direction). Upper surfaces of the gate electrode layers 130a and 130b may be flat (e.g., where the first region R1 meets the second region R2), and lower surfaces of the gate electrode layers 130a and 130b may have a step between the first region R1 and the second region R2 (e.g., where the first region R1 meets the second region R2). In the case of FIG. 4A, a boundary of the gate electrode layers 130a and 130b between the first region R1 and the second region R2 may have a surface perpendicular to the upper surface of the semiconductor layer 110, but in the case of FIG. 4B, a boundary of the gate electrode layers 130a and 130b between the first region R1 and the second region R2 may have a surface inclined with respect to the upper surface of the semiconductor layer 110. In an example embodiment, the lower surface of the entire first region R1 for each gate electrode layer may be inclined with respect to the upper surface of the semiconductor layer 110. Each gate electrode layer 130 may include a first conductive layer 131 and a second conductive layer 133. The first conductive layer 131 may be, for example, a metal nitride such as titanium nitride, and the like, and the second conductive layer 133 may be, for example, a metal such as tungsten, and the like.

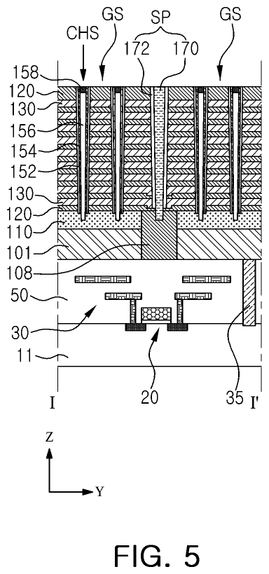

FIG. 5 is a cross-sectional view illustrating a vertical memory device according to an example embodiment. Since FIG. 5 is similar to the cross-sectional view taken along line I-I′ of FIG. 2, only differences from the cross-sectional view taken along I-I′ of FIG. 2 will be described below.

Referring to FIG. 5, a lower end of one or more vertical channel structures CHS' may be inserted into the upper portion of the semiconductor layer 110. A lower end of the gate insulating layer 152, a lower end of the channel 154, and a lower end of the gap fill insulating layer 156 may be inserted into (e.g., may extend into) the upper portion of the semiconductor layer 110. Each of the lower end of the gate insulating layer 152, the lower end of the channel 154, and the lower end of the gap fill insulating layer 156 may be located higher than a lower surface of the semiconductor layer 110. The lower end of the gap fill insulating layer 156 may be inserted into the semiconductor layer 110, deeper than the lower end of the channel 154 and the lower end of the gate insulating layer 152. For example, the lower end of the gap fill insulating layer 156 may be located lower than the lower end of the channel 154.

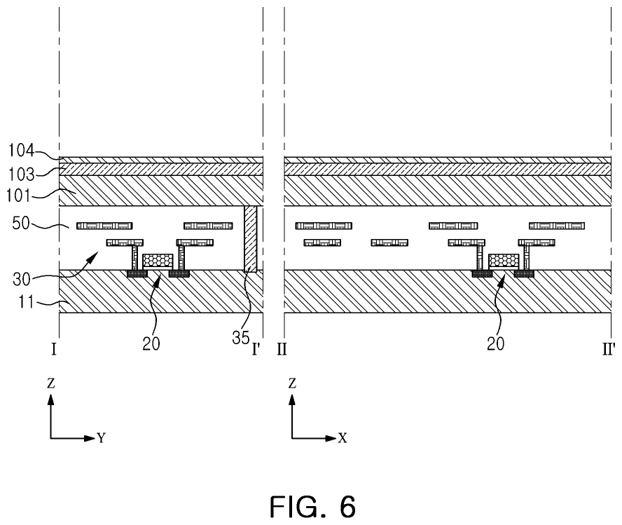

FIGS. 6 to 17 are schematic cross-sectional views illustrating a manufacturing method of a vertical memory device according to an example embodiment.

Referring to FIG. 6, transistors 20, circuit wirings 30, an interlayer insulating layer 50, and a contact plug 35 are formed on a base substrate 11.

The base substrate 11 may be formed of a semiconductor material, such as a Group IV semiconductor, a Group III-V compound semiconductor or a Group II-VI compound semiconductor. The Group IV semiconductor may be silicon, germanium or silicon-germanium. For example, the base substrate 11 may include single-crystal silicon. In the embodiment of FIGS. 6-17, the transistors 20 and the circuit wirings 30 constitute a peripheral circuit. The transistors 20 may include planar transistors, as well as various types of transistors. The contact plug 35 penetrates the interlayer insulating layer 50.

A substrate 101, a first sacrificial semiconductor layer 103, and a second sacrificial semiconductor layer 104 are sequentially stacked on the interlayer insulating layer 50. The substrate 101, the first sacrificial semiconductor layer 103, and the second sacrificial semiconductor layer 104 may each be formed of a semiconductor material, such as a Group IV semiconductor, a Group III-V compound semiconductor, or a Group II-VI compound semiconductor. For example, the substrate 101, the first sacrificial semiconductor layer 103, and the second sacrificial semiconductor layer 104 may each be formed of a polycrystalline silicon. For example, in one embodiment, the substrate 101 is an undoped polycrystalline silicon, or polycrystalline silicon including n-type impurities. In this embodiment, the first sacrificial semiconductor layer 103 may be polycrystalline silicon including p-type impurities. The second sacrificial semiconductor layer 104 may be undoped polycrystalline silicon, or polycrystalline silicon including n-type impurities. Each of the substrate 101 and the second sacrificial semiconductor layer 104 may have the same material composition (e.g., undoped polycrystalline silicon, or polycrystalline silicon including n-type impurities), or the substrate 101 may have a different material composition than the second sacrificial layer 104 (e.g., one may be undoped polycrystalline silicon and the other is polycrystalline silicon including n-type impurities).

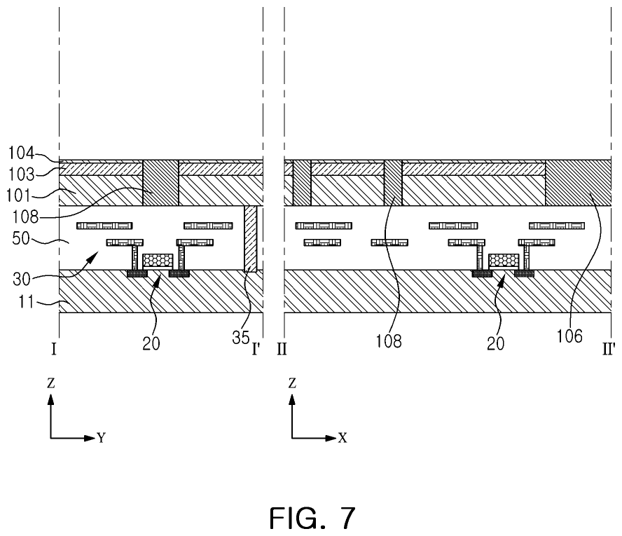

Referring to FIG. 7, supporting insulating layers 108 penetrating the substrate 101, the first sacrificial semiconductor layer 103, and the second sacrificial semiconductor layer 104 are formed. An interlayer insulating layer 106 surrounding the substrate 101, the first sacrificial semiconductor layer 103, and the second sacrificial semiconductor layer 104 is also formed.

For example, by removing portions of the substrate 101, the first sacrificial semiconductor layer 103, and the second sacrificial semiconductor layer 104, and then by filling spaces from which portions of the substrate 101, the first sacrificial semiconductor layer 103, and the second sacrificial semiconductor layer 104 are removed with an insulating material, the supporting insulating layers 108 and the interlayer insulating layer 106 may be formed.

A step of forming the supporting insulating layers 108 and the interlayer insulating layer 106 may include a chemical mechanical polishing (CMP) process, whereby a thickness of the second sacrificial semiconductor layer 104 is reduced.

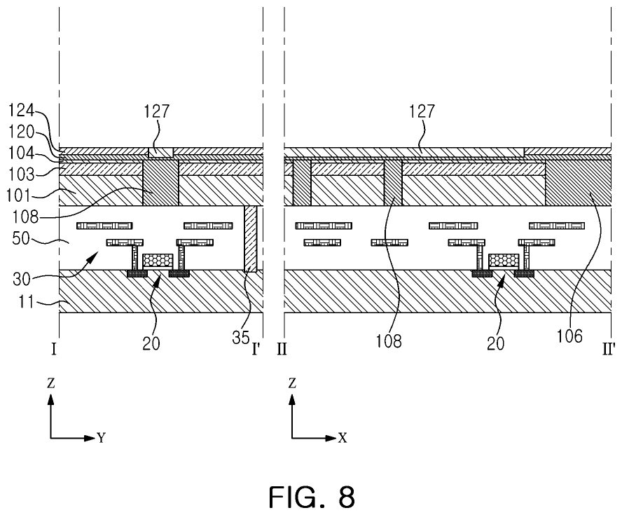

Referring to FIG. 8, a mold insulating layer 120 and a sacrificial layer 124 are stacked on the structure of FIG. 7. After removing a portion of the sacrificial layer 124 to form a trench overlapping the supporting insulating layers 108 in a vertical direction and extending in the first direction (x direction), and then by filling the trench with a semiconductor material, a linear stopper 127 extending in the first direction (x direction) is formed. In one embodiment, a bottom of the trench, for example, a lower surface of the stopper 127 is lower than the upper surface of the mold insulating layer 120. The stopper 127 may be formed of undoped polycrystalline silicon, or polycrystalline silicon including n-type impurities. The mold insulating layer 120 may be, for example, silicon oxide, and the sacrificial layer 124 may be, for example, silicon nitride.

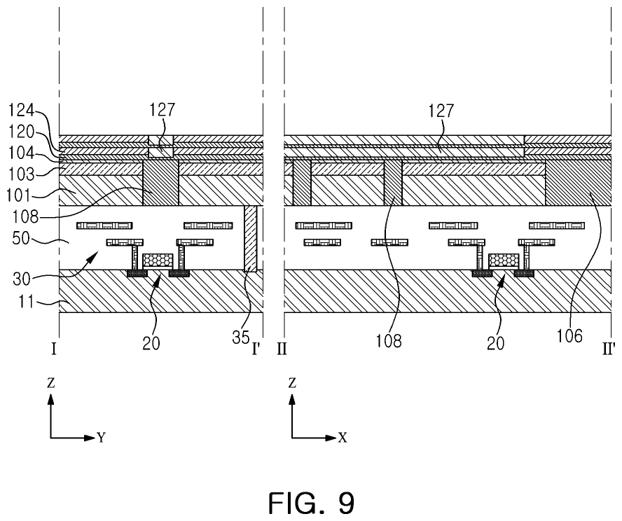

Referring to FIG. 9, by performing the same or similar process as the process of FIG. 8, two stoppers 127 may be stacked on the supporting insulating layers 108.

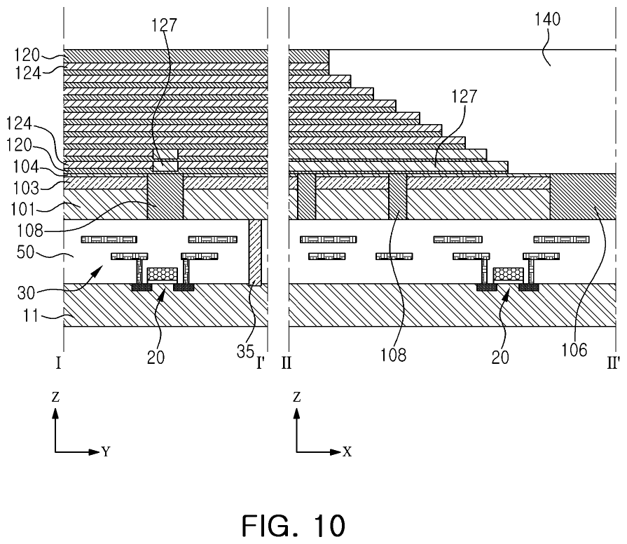

Referring to FIG. 10, after mold insulating layers 120 and sacrificial layers 124 are repeatedly stacked on the structure of FIG. 9, a portion of the mold insulating layers 120, a portion of the sacrificial layers 124, and a portion of the stoppers 127 are etched to form a stepped structure in a connection region CT (see FIG. 1). An interlayer insulating layer 140 covering the stepped structure is formed.

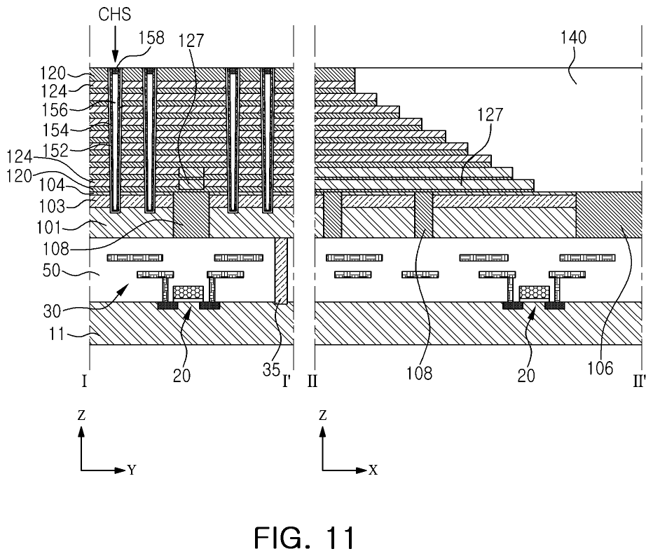

Referring to FIG. 11, vertical structures CHS penetrating mold insulating layers 120, sacrificial layers 124, a first sacrificial semiconductor layer 103, and a second sacrificial semiconductor layer 104 in a direction perpendicular to the upper surface of the substrate 101 are formed in a cell array region CA (see FIG. 1). In the embodiment of FIG. 11, lower portions of the vertical structures CHS are inserted into (e.g., extend into) the upper portion of the substrate 101.

The vertical structure CHS may include a gate insulating layer 152, a channel 154, a gap fill insulating layer 156, and a pad 158.

After forming channel holes penetrating the mold insulating layers 120, the sacrificial layers 124, the first sacrificial semiconductor layer 103, and the second sacrificial semiconductor layer 104 in a direction perpendicular to the upper surface of the substrate 101 in the cell array region CA, the gate insulating layer 152, the channel 154, and the gap fill insulating layer 156 may be sequentially formed within the channel holes. A chemical mechanical polishing process may be performed to remove the gate insulating layer 152, the channel 154, and the gap fill insulating layer 156, formed on the mold insulating layer 120. After removing a portion of the gap fill insulating layer 156, a pad 158 may be formed.

The gate insulating layer 152 may include a tunneling layer, a charge storage layer, and a blocking layer. The tunneling layer may include, for example, silicon oxide. The charge storage layer may include silicon nitride. The blocking layer may include silicon oxide (SiO₂), silicon nitride (Si₃N₄), silicon oxynitride (SiON), a high dielectric constant (high-k) material, or a combination thereof.

The channel 154 may be, for example, undoped polycrystalline silicon. The gap fill insulating layer 156 may be, for example, silicon oxide. The pad 158 may be, for example, polycrystalline silicon including n-type impurities.

In an example embodiment, the channel holes may be formed to penetrate the mold insulating layers 120, the sacrificial layers 124, and the second sacrificial semiconductor layer 104. In this case, the lower portions of the vertical structures CHS may be inserted into (e.g., extend into) the upper portion of the first sacrificial semiconductor layer 103 and may terminate within the first sacrificial semiconductor layer 103.

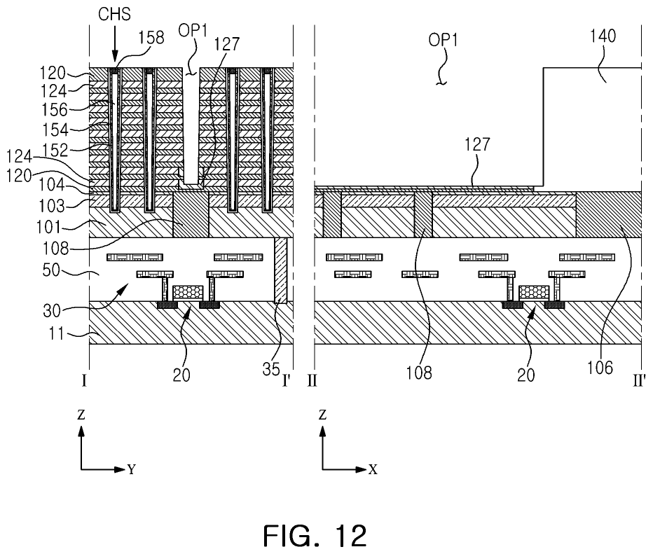

Referring to FIG. 12, an anisotropic etching process may be performed to form a first opening OP1 penetrating the mold insulating layers 120 and the sacrificial layers 124, and extending in the first direction (x direction). A lower end of the first opening OP1 may be located in the stopper 127, adjacent to the supporting insulating layer 108.

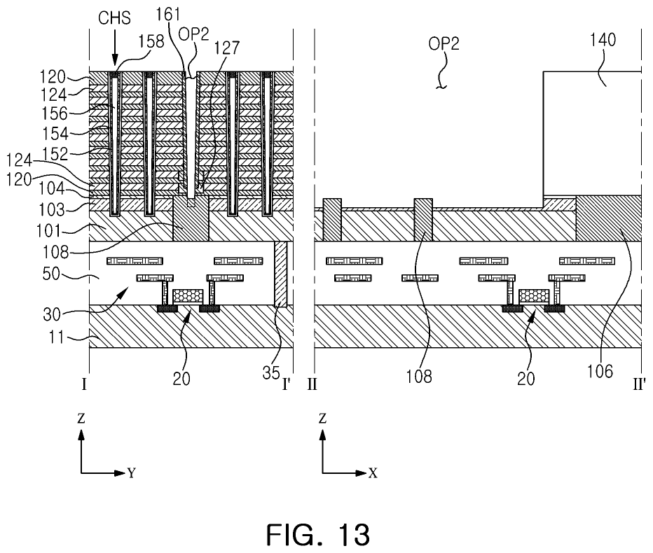

Referring to FIG. 13, after forming a spacer 161 on a sidewall of the first opening OP1, a second opening OP2 is formed, for example, by an anisotropic etching process. The second opening OP2 may penetrate a second sacrificial semiconductor layer 104, and may expose a portion of the first sacrificial semiconductor layer 103. A lower end of the second opening OP2 may be located in the first sacrificial semiconductor layer 103. The second opening OP2 may expose the supporting insulating layers 108. In an example embodiment, the second opening OP2 also penetrates through the first sacrificial semiconductor layer 103, and exposes the upper portion of the substrate 101. The spacer 161 may be formed of, for example, undoped polycrystalline silicon, or polycrystalline silicon including n-type impurities.

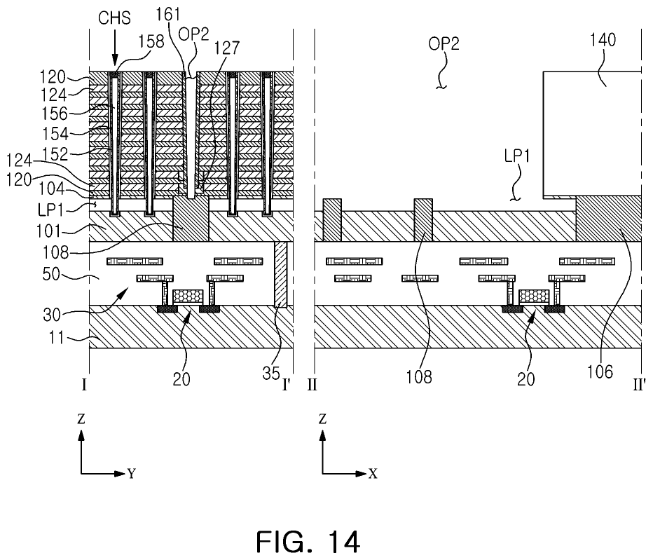

Referring to FIG. 14, the first sacrificial semiconductor layer 103 exposed by the second opening OP2 is completely removed to form a first lateral opening LP1, located between the second sacrificial semiconductor layer 104 and the substrate 101. A portion of the gate insulating layer 152 of the vertical structures CHS exposed by the first lateral opening LP1 may be removed in this process. In one embodiment, a portion of the channel 154 of the vertical structures CHS is exposed by the first lateral opening LP1, and portions of side surfaces of the supporting insulating layers 108 are exposed.

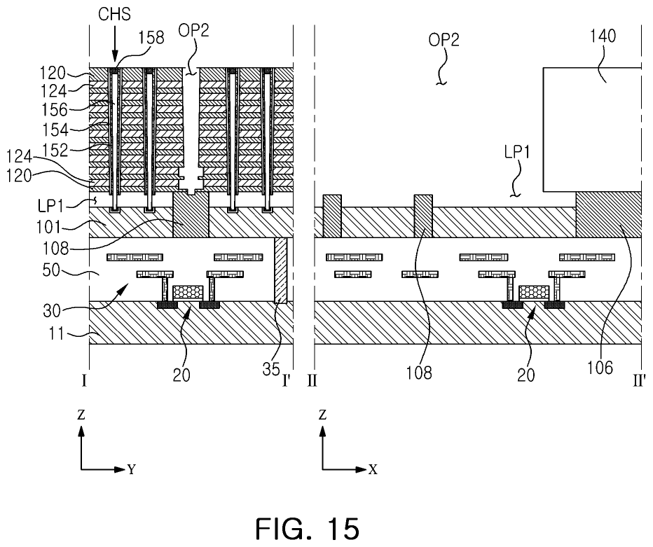

Referring to FIG. 15, a spacer 161 and stoppers 127 are removed through the second opening OP2. The second sacrificial semiconductor layer 104 and a portion of the channel 154 may also be removed together through the first lateral opening LP1. In one embodiment, a portion of the substrate 101 is also removed in this process. As a result, a portion of the gap fill insulating layer 156 is exposed by the first lateral opening LP1.

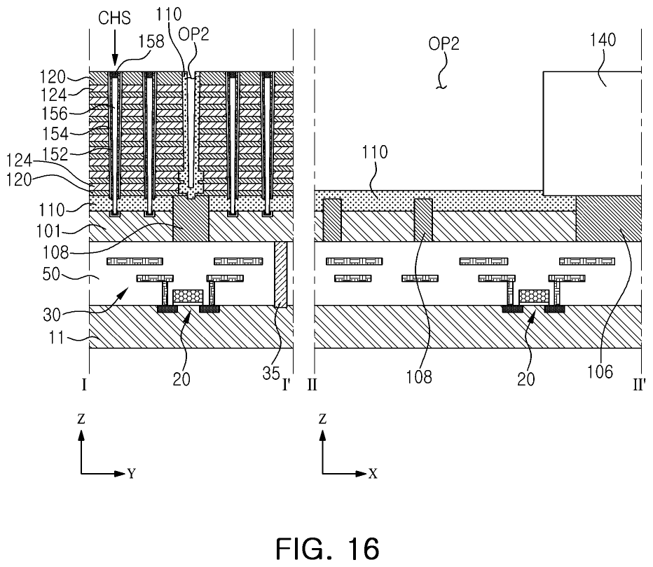

Referring to FIG. 16, a semiconductor layer 110 filling the first lateral opening LP1 is formed. In this case, the semiconductor layer 110 is also formed in the second opening OP2. The semiconductor layer 110 may be polycrystalline silicon including n-type impurities. For example, the n-type impurities included in the semiconductor layer 110 may be partially diffused into the channel 154.

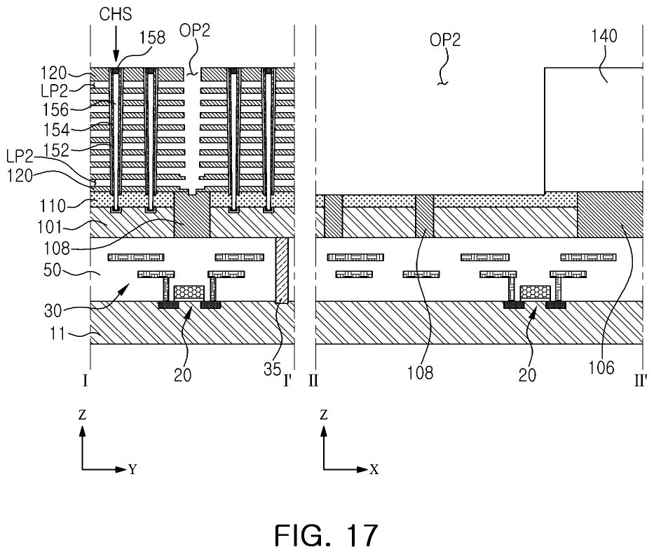

Referring to FIG. 17, by removing the semiconductor layer 110 in the second opening OP2 first, and removing the sacrificial layers 124 exposed by the second opening OP2, a second lateral opening LP2 exposing the gate insulating layers 152 of the vertical structures CHS is formed. In this manner, the semiconductor layer 110 penetrates the gate insulating layers 152 and the channels 154.

Referring again to FIG. 2, gate electrode layers 130 are formed in the second lateral openings LP2, and a separation pattern SP is formed in the second opening OP2. The separation pattern SP may include a conductive layer 170, in contact with the semiconductor layer 110 and an insulating layer 172 in a spacer form. The gate electrode layers 130 and the conductive layer 170 may be insulated by the insulating layer 172. For example, material that forms the gate electrode layers 130 may be filled into the second lateral openings LP2 and the second opening OP2, then the material may be removed from the second opening OP2 to form a third opening, for example using an etching process or other process, and then an insulating material may line the third opening to form the insulating layer 172, and be filled with a conductive material to form the conductive layer 170. Alternatively, the insulating material may completely fill the third opening, and then may be partially removed (e.g., a central portion thereof), and then the resulting opening may be filled with the conductive material to form the conductive layer 170. As shown in FIG. 2, each separation pattern SP, and particularly, each conductive layer 170, extends to be formed in a trench of a respective supporting insulating layer 108 that it vertically overlaps.

As a result of the above process, one or more mold insulating layers 120 at a bottom of an alternating mold insulating layer/gate electrode stack (e.g., two such layers are shown in FIG. 2) may have a shape next to a separation pattern or separation structure that has a smaller vertical thickness closer to the separation pattern than the vertical thickness further away from the separation pattern. At the same time, remaining mold insulating layers 120 other than the one or more with this shape can have a uniform thickness that is the same closer to the separation pattern as it is further away from the separation pattern. One or more gate electrodes 130 at a bottom of the alternating mold insulating layer/gate electrode stack may have a shape next to a separation pattern or separation structure that has a greater vertical thickness closer to the separation pattern than the vertical thickness further away from the separation pattern. At the same time, remaining gate electrodes 130 other than the one or more with this shape can have a uniform thickness that is the same closer to the separation pattern as it is further away from the separation pattern.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

As set forth above, according to example embodiments, a vertical memory device is provided in which a manufacturing process of a process of etching channel holes or the like is simplified, and operational reliability is improved.

The various and advantageous advantages and effects of the present invention are not limited to the above description, and can be more easily understood in the course of describing a specific embodiment of the present invention.

While example embodiments have been shown and described above, it will be apparent to those skilled in the art that modifications and variations could be made without departing from the scope of the present invention as defined by the appended claims.

What is claimed is:

1. A vertical memory device comprising:
a semiconductor layer disposed on a substrate;
a first gate electrode layer and a second gate electrode layer stacked on the semiconductor layer;
separation patterns penetrating the first gate electrode layer and the second gate electrode layer in a direction perpendicular to an upper surface of the substrate, and extending in a direction parallel to the upper surface of the substrate; and
supporting insulating layers penetrating the semiconductor layer and the substrate, and disposed below the separation patterns to respectively vertically overlap the separation patterns.

2. The vertical memory device of claim 1, wherein each of the first gate electrode layer and the second gate electrode layer has a first region, adjacent to a separation pattern and a second region, adjacent to the first region, wherein the first region is disposed between the separation pattern and the second region, and a thickness of the first region in the direction perpendicular to the upper surface of the substrate is greater than a thickness of the second region in the direction perpendicular to the upper surface of the substrate.

3. The vertical memory device of claim 2, wherein the upper surface of each of the first and second gate electrode layers, adjacent to the supporting insulating layers is flat, and the lower surface thereof has a step.

4. The vertical memory device of claim 1, wherein the separation patterns comprise a conductive layer, and the conductive layer contacts respective supporting insulating layers and the semiconductor layer.

5. The vertical memory device of claim 4, wherein a lower surface of each conductive layer is lower than an upper surface of the semiconductor layer.

6. The vertical memory device of claim 1, further comprising a vertical structure penetrating the first gate electrode layer, the second gate electrode layer, and the semiconductor layer, and including a channel contacting the semiconductor layer and a gap fill insulating layer surrounded by the channel,
wherein a lower end of the gap fill insulating layer is located lower than the upper surface of the substrate.

7. The vertical memory device of claim 6, wherein the semiconductor layer penetrates the channel and contacts a side surface of the gap fill insulating layer.

8. The vertical memory device of claim 7, wherein the vertical structure further comprises a gate insulating layer surrounding the channel, and
the semiconductor layer penetrates the gate insulating layer and the channel.

9. The vertical memory device of claim 1, further comprising a vertical structure penetrating the first gate electrode layer and the second gate electrode layer, and including a channel contacting semiconductor layer and a gap fill insulating layer surrounded by the channel,
wherein each of the channel and the gap fill insulating layer extends into an upper portion of the semiconductor layer, and each of a lower end of the channel and a lower end of the gap fill insulating layer is located higher than a lower surface of the semiconductor layer.

10. The vertical memory device of claim 9, wherein the lower end of the gap fill insulating layer is located lower than the lower end of the channel.

11. The vertical memory device of claim 1, further comprising:
a base substrate disposed below the substrate; and
transistors disposed on the base substrate and constituting a peripheral circuit.

12. A vertical memory device comprising:
a semiconductor layer disposed on a substrate;
supporting insulating layers penetrating the semiconductor layer and the substrate;
separation patterns disposed on the semiconductor layer and overlapping the supporting insulating layers in a direction perpendicular to an upper surface of the substrate;
a stack structure disposed between the separation patterns, and including a plurality of gate electrode layers stacked on the substrate; and
vertical structures penetrating the stack structure, each vertical structure including a channel that contacts the semiconductor layer.

13. The vertical memory device of claim 12, wherein:
a first gate electrode layer among the plurality of gate electrode layers, adjacent to the supporting insulating layers, has a first region, adjacent to a separation pattern, and a second region, adjacent to the first region, wherein the first region is disposed between the second region and the separation pattern, and
a thickness of the first region in the direction perpendicular to the upper surface of the substrate is greater than a thickness of the second region in the direction perpendicular to the upper surface of the substrate.

14. The vertical memory device of claim 13, wherein the upper surface of the first gate electrode layer, adjacent to the supporting insulating layers is flat, and the lower surface thereof has a step.

15. The vertical memory device of claim 12, wherein the separation patterns each comprise a conductive layer, and each conductive layer contacts respective supporting insulating layers and the semiconductor layer.

16. The vertical memory device of claim 15, wherein for at least one separation pattern, a lower portion of the conductive layer extends into an upper portion of a supporting insulating layer.

17. The vertical memory device of claim 12, wherein:
each vertical structure further comprises a gap fill insulating layer surrounded by a respective channel,
the gap fill insulating layer penetrates the semiconductor layer and extends into the upper portion of the substrate, and
the semiconductor layer contacts a side surface of the gap fill insulating layer.

18. The vertical memory device of claim 12, wherein:
each vertical structure further comprises a gap fill insulating layer surrounded by a respective channel, and
each of the channel and the gap fill insulating layer extends into an upper portion of the semiconductor layer, and each of a lower end of the channel and a lower end of the gap fill insulating layer is located higher than a lower surface of the semiconductor layer.

19. A vertical memory device comprising:
a base substrate;
transistors disposed on the base substrate and constituting a peripheral circuit;
an interlayer insulating layer covering the transistors;
a substrate disposed on the interlayer insulating layer, and having a smaller size than that of the base substrate;
a semiconductor layer disposed on the substrate;
supporting insulating layers penetrating the semiconductor layer and the substrate;
a stack structure including a plurality of gate electrode layers stacked on the semiconductor layer;
separation patterns penetrating the stack structure and overlapping the supporting insulating layers in a direction perpendicular to the upper surface of the substrate; and
vertical structures penetrating the stack structure, each including a channel that contacts the semiconductor layer.

20. The vertical memory device of claim 19, wherein:
a first gate electrode layer among the plurality of gate electrode layers and adjacent to the supporting insulating layers has a first region, adjacent to a separation pattern and a second region, adjacent to the first region so that the first region is disposed between the separation pattern and the second region,
a thickness of the first region in the direction perpendicular to the upper surface of the substrate is greater than a thickness of the second region in the direction perpendicular to the upper surface of the substrate, and
the upper surface of the first gate electrode layer is flat, and the lower surface thereof has a step between the first region and the second region.
